(19) United States
(12) Patent Application Publication
(10) Pub. No.: US 2016/0035416 A1
(43) Pub. Date: Feb. 4, 2016

(54) NONVOLATILE MEMORY DEVICE AND METHOD FOR DRIVING SAME

(71) Applicant: Kabushiki Kaisha Toshiba, Minato-ku (JP)

(72) Inventors: Kikuko SUGIMAE, Kuwana (JP); Reika Ichihara, Yokohama (JP)

(73) Assignee: Kabushiki Kaisha Toshiba, Minato-ku (JP)

(21) Appl. No.: 14/640,478

(22) Filed: Mar. 6, 2015

Related U.S. Application Data
(60) Provisional application No. 62/031,631, filed on Jul. 31, 2014.

(51) Int. Cl. G11C 13/00; H01L 45/00

(52) U.S. Cl. CPC G11C 13/004; G11C 13/0069; G11C 13/0064; H01L 45/08; H01L 45/1233; G11C 2013/009; G11C 2013/005

(57) ABSTRACT

According to one embodiment, a nonvolatile memory device includes: a first interconnection layer; a second interconnection layer; an ion source provided between the first interconnection layer and the second interconnection layer; a resistance layer provided between the ion source and the first interconnection layer; and a control circuit writing multi-value data in the resistance layer by changing a setting voltage to be applied between the first interconnection layer and the second interconnection layer when performing a setting operation of writing data in the resistance layer, and the control circuit reading the multi-value data based on reading voltage to be applied between the first interconnection layer and the second interconnection layer when performing a reading operation of reading the multi-value data.

### CROSS-REFERENCE TO RELATED APPLICATIONS

This application is based upon and claims the benefit of priority from U.S. Provisional Patent Application 62/031,631, filed on Jul. 31, 2014; the entire contents of which are incorporated herein by reference.

### FIELD

Embodiments described herein relate generally to a nonvolatile memory device and a method for driving the same.

### BACKGROUND

In recent years, a circuit pattern of an LSI element has become fine as the degree of integration of a semiconductor device has increased. In order to realize the fine pattern, it is necessary that a line width become fine, and it is also necessary that the accuracy of the size or position of the pattern become fine. Similarly, in a memory device, it is necessary that a certain amount of charge necessary for storage be retained in a narrow region in a fine cell.

In recent years, as a technique for solving the above problem, a nonvolatile memory device in which a memory cell is configured by a resistance changing layer has been proposed. Since this nonvolatile memory device has a three-dimensional stacking structure, it is possible to enhance the degree of integration compared with a memory cell that uses a two-dimensional plane. However, as the degree of integration increases, high reliability is necessary for a writing operation.

### BRIEF DESCRIPTION OF THE DRAWINGS

FIG. 1 is a perspective view schematically illustrating a nonvolatile memory device according to an embodiment;

FIG. 2 is a diagram schematically illustrating an operation of a device of a nonvolatile memory device according to the embodiment;

FIG. 3A is an example of a diagram illustrating a resistance-voltage curve of a current limiting layer according to the embodiment, and FIG. 3B is an example of a diagram illustrating a voltage pulse during the setting operation according to the embodiment;

FIG. 4 is a diagram schematically illustrating binary recording according to the embodiment;

FIG. 5 is a diagram schematically illustrating the multi-value recording according to the embodiment;

FIG. 6 is a diagram illustrating the flow of writing according to the embodiment; and

FIG. 7 is a diagram illustrating the flow of reading according to the embodiment.

### DETAILED DESCRIPTION

In general, according to one embodiment, a nonvolatile memory device includes: a first interconnection layer; a second interconnection layer; an ion source provided between the first interconnection layer and the second interconnection layer; a resistance layer provided between the ion source and the first interconnection layer; and a control circuit writing multi-value data in the resistance layer by changing a setting voltage to be applied between the first interconnection layer and the second interconnection layer when performing a setting operation of writing data in the resistance layer, and the control circuit reading the multi-value data based on reading voltage to be applied between the first interconnection layer and the second interconnection layer when performing a reading operation of reading the multi-value data.

Hereinafter, exemplary embodiments will be described with reference to the accompanying drawings. In the following description, the same reference numerals are given to the same members, and description of components described once may not be repeated.

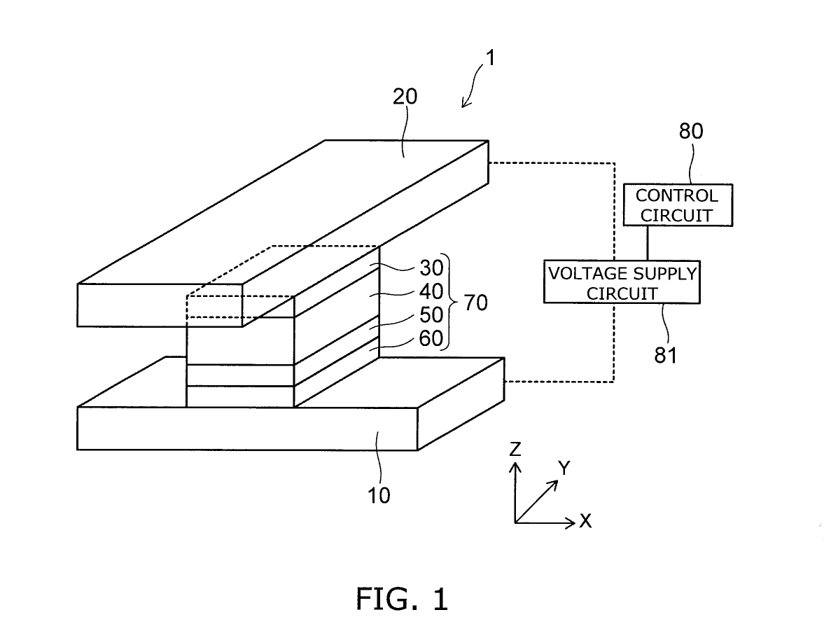

FIG. 1 is a perspective view schematically illustrating a nonvolatile memory device according to an exemplary embodiment.

A nonvolatile memory device 1 includes an interconnection layer 10 (a first interconnection layer), an interconnection layer 20 (a second interconnection layer), a metal ion-source layer (ion source) 30, a resistance changing layer (resistance layer) 40, a metal layer 50, and a current limiting layer 60. The metal ion-source layer 30, the resistance changing layer 40, the metal layer 50, and the current limiting layer 60 are referred to as a storage cell 70. Further, the nonvolatile memory device 1 includes a voltage supply circuit 81 capable of supplying a potential to the interconnection layer 10 and the interconnection layer 20, and a control circuit 80 that controls the voltage supply circuit 81.

The control circuit 80 may control each potential of the interconnection layer 10 and the interconnection layer 20 to thereby detect a reading voltage to be applied to the resistance changing layer 40 whose resistance is changeable.

Further, when a setting operation of performing data writing in the resistance changing layer 40 is performed, the control circuit 80 changes a setting voltage applied between the interconnection layer 10 and the interconnection layer 20 or an application time of the setting voltage, to thereby write multi-value data in the resistance changing layer 40. Further, when a reading operation of reading each piece of the multi-value data is performed, the control circuit 80 may read the multi-value data based on a difference of the reading voltages to be applied between the interconnection layer 10 and the interconnection layer 20. Details of writing and reading will be described later.

First, a device structure of the nonvolatile memory device 1 excluding the voltage supply circuit 81 and the control circuit 80 will be described.

The interconnection layer 10 is a bit line, for example, and the interconnection layer 20 is a word line, for example. Alternatively, the interconnection layer 10 may be the word line, and the interconnection layer 20 may be the bit line. The interconnection layer 10 extends in the X-direction (first direction). The interconnection layer 20 extends in the Y-direction (second direction) intersecting the X-direction. At a position where the interconnection layer 10 and the interconnection layer 20 intersect, the storage cell 70 (the metal ion-source layer 30, the resistance changing layer 40, the metal layer 50, and the current limiting layer 60) is provided. The metal layer 50 may be appropriately removed from the storage cell 70.

The metal ion-source layer 30 is provided between (hereinafter, referred to as between interconnections) the interconnection layer 10 and the interconnection layer 20. For example, the metal ion-source layer 30 includes at least one element of Au, Ag, Pd, Ir, Pt, W, Hf, Zr, Ti, Ni, Co, Al, Cr, Cu, and the like.

The resistance changing layer 40 is provided between the metal ion-source layer 30 and the interconnection layer 10. In the resistance changing layer 40, metal ions discharged from the metal ion-source layer 30 may be diffused therein.

The resistance changing layer 40 is a layer including silicon, oxygen, metal or the like. For example, the resistance changing layer 40 includes silicon oxide (SiOₓ), polysilicon, alumina, hafnia or the like. The resistance changing layer 40 may be a stacked body obtained by combining arbitrary films of a silicon oxide film, a polysilicon film, an alumina film, and a hafnia film. Such a layer serves as a base metal of the resistance changing layer 40.

The resistance of the resistance changing layer 40 may be changed by diffusing the metal ions discharged from the metal ion-source layer 30 into the base metal, or by returning the diffused metal ions to the metal ion-source layer 30 (which will be described later).

Thus, in the case of binary storage, the resistance of the resistance changing layer 40 is reversibly in a low resistance state (data: 1) or in a high resistance state (data: 0). In the exemplary embodiment, an operation of setting the resistance of the resistance changing layer 40 to the low resistance state is referred to as the setting operation, and an operation of setting the resistance of the resistance changing layer 40 to the high resistance state is referred to as a reset operation. Further, the voltage in the reset operation is referred to as a reset voltage.

The current limiting layer 60 is provided between the interconnection layer 10 and the resistance changing layer 40. The current limiting layer 60 may be provided between the interconnection layer 20 and the metal ion-source layer 30. The metal layer 50 is provided between the resistance changing layer 40 and the current limiting layer 60. The current limiting layer 60 is a high resistance layer having conductivity to some degree. The current limiting layer 60 includes at least one element of Mo, W, Ta, Ti, Si, Ge, C, Ga, As, N, P, and the like, for example. The resistivity of the current limiting layer 60 is, for example, 1 Ω·cm to 10⁸ Ω·cm.

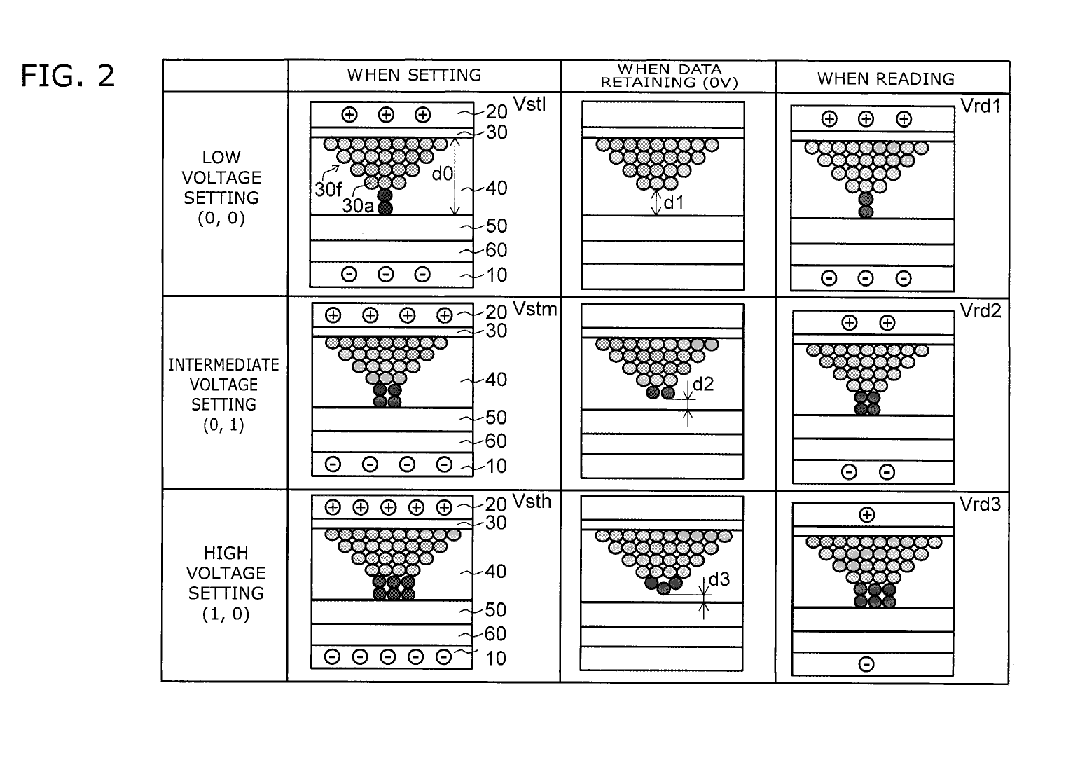

FIG. 2 is a diagram schematically illustrating an operation of a device of a nonvolatile memory device according to an exemplary embodiment.

FIG. 2 shows a first setting operation (upper part), a second setting operation (intermediate part), and a third setting operation (lower part). The phenomenon shown in FIG. 2 is schematic, and the invention is not limited to the phenomenon.

First, the first setting operation shown in the upper part in FIG. 2 will be described. The first setting operation is a low voltage setting operation.

During the low voltage setting, a relatively low voltage (Vstl) is applied between the interconnections. Here, the potential of the interconnection layer 20 is higher than the potential of the interconnection layer 10. Thus, metal ions 30a are discharged toward the resistance changing layer 40 from the metal ion-source layer 30, so that a filament 30f is formed in the resistance changing layer 40. The filament 30f includes the metal ions 30a.

After application of the voltage (Vstl), if the voltage (Vstl) is continuously applied between the interconnections, a lower end of the filament 30f comes in contact with the metal layer 50. Thus, the resistance of the resistance changing layer 40 is changed into a resistance value R1 (second resistance value) lower than a resistance value R0 (first resistance value) before application of the voltage (Vstl). That is, the resistance of the resistance changing layer 40 that is in the high resistance state before contact transitions to the low resistance state. That is, the resistance of the resistance changing layer 40 is set to the resistance value R1 by application of the voltage (Vstl), and thus, data (0, 0) is written in the nonvolatile memory device 1.

Then, if the low voltage setting is completed, a state where the voltage is not applied (0 V) is continued between the interconnections, for example. In a state where the voltage is not applied, the resistance changing layer 40 maintains a state where the lower end of the filament 30f is slightly separated from the metal layer 50. That is, the resistance changing layer 40 maintains a data retaining state.

Then, when reading the written data, a voltage (Vrd1) of such a degree that the lower end of the filament 30f comes in contact with the metal layer 50 again is applied between the interconnections. This voltage is referred to as a reading voltage (Vrd1).

If the reading voltage (Vrd1) is applied between the interconnections, the lower end of the filament 30f comes in contact with the metal layer 50 again. That is, by applying the reading voltage (Vrd1), it is detected that the resistance changing layer 40 is in the low resistance state (R1).

There is a relationship of “reading voltage (vrd1)<voltage (Vstl)” between the reading voltage (Vrd1) and the voltage (Vstl). This is because the filament 30f is already formed in the resistance changing layer 40 when the reading voltage (Vrd1) is applied. That is, this is because the distance between the filament 30f and the metal layer 50 is substantially d0 before the low voltage setting, but the distance between the filament 30f and the metal layer 50 becomes d1 (<d0) that is shorter than d0 in the data retaining state.

In this way, after the resistance of the resistance changing layer 40 becomes the resistance value R1, the setting voltage application between the interconnections is stopped. Then, the reading voltage (Vrd1) lower than the voltage (Vstl) is applied between the interconnections again, to detect whether the resistance of the resistance changing layer 40 is changed into the resistance value R1 from the resistance value R0.

Next, the second setting operation shown in the intermediate part in FIG. 2 will be described. The second setting operation is an intermediate voltage setting operation.

During the intermediate voltage setting, a voltage (Vstm) higher than the voltage (Vstl) is applied between the interconnections. Here, the potential of the interconnection layer 20 is higher than the potential of the interconnection layer 10. Thus, the metal ions 30a are discharged toward the resistance changing layer 40 from the metal ion-source layer 30, and thus, the filament 30f is formed in the resistance changing layer 40.

If the voltage (Vstm) is continuously applied between the interconnections, the lower end of the filament 30f comes in contact with the metal layer 50. Thus, the resistance of the resistance changing layer 40 is changed into the resistance value R1. That is, the resistance of the resistance changing layer 40 that is in the high resistance state before contact transitions to the low resistance state.

Here, in the intermediate voltage setting, since a higher current flows compared with the case of the low voltage setting, a stronger filament 30f is formed. Here, the stronger filament 30f means a thicker filament, a denser filament, or the like. For example, a high current may flow into the filament 30f formed by the intermediate voltage setting compared with the filament 30f formed by the low voltage setting.

Then, if the intermediate voltage setting is completed, a state where the voltage is not applied (0 V) is continued between the interconnections, for example. In a state where the voltage is not applied, the resistance changing layer 40 maintains a state where the lower end of the filament 30f is slightly separated from the metal layer 50. That is, the resistance changing layer 40 maintains a data retaining state.

However, in the intermediate voltage setting, since the strong filament 30f is formed in the resistance changing layer 40 compared with the low voltage setting, the distance between the filament 30f and the metal layer 50 becomes d2 (<d1) shorter than d1 in the data retaining state. Data written in the nonvolatile memory device 1 in the intermediate voltage setting is set to (0, 1), for example.

Then, when reading the written data, a voltage (Vrd2) of such a degree that the lower end of the filament 30f comes in contact with the metal layer 50 again is applied between the interconnections. This voltage is referred to as a reading voltage (Vrd2).

If the reading voltage (Vrd2) is applied between the interconnections, the lower end of the filament 30f comes in contact with the metal layer 50 again. That is, by applying the reading voltage (Vrd2), it is detected that the resistance changing layer 40 is in the low resistance state (R1).

There is a relationship of “reading voltage (Vrd2)<voltage (Vstm)” between the reading voltage (Vrd2) and the voltage (Vstm). This is because the filament 30f is already formed in the resistance changing layer 40 when the reading voltage (Vrd2) is applied. That is, this is because the distance between the filament 30f and the metal layer 50 is substantially d0 before the intermediate voltage setting, but the distance between the filament 30f and the metal layer 50 becomes d2 shorter than d0 in the data retaining state.

Further, there is a relationship of “reading voltage (Vrd2)<reading voltage (Vrd1)” between the reading voltage (Vrd2) and the reading voltage (Vrd1). This is because there is a relationship of d2<d1 in the distance between the filament 30f and the metal layer 50 in the data retaining state.

Next, the third setting operation shown in the lower part of FIG. 2 will be described. The third setting operation is a high voltage setting operation.

During the high voltage setting, a voltage (Vsth) higher than the voltage (Vstm) is applied between the interconnections. Here, the potential of the interconnection layer 20 is higher than the potential of the interconnection layer 10. Thus, the metal ions 30a are discharged toward the resistance changing layer 40 from the metal ion-source layer 30, so that the filament 30f is formed in the resistance changing layer 40.

If the voltage (Vsth) is continuously applied between interconnections, the lower end of the filament 30f comes in contact with the metal layer 50. Thus, the resistance of the resistance changing layer 40 is changed into the resistance value R1. That is, the resistance of the resistance changing layer 40 transitions to the low resistance state from the high resistance state.

Here, during the high voltage setting, since a higher current flows compared with the case of the intermediate voltage setting, a stronger filament 30f is formed. A high current may flow into the filament 30f formed by the high voltage setting compared with the filament 30f formed by the intermediate voltage setting.

Then, if the high voltage setting is completed, a state where the voltage is not applied (0 V) is continued between the interconnections, for example. In a state where the voltage is not applied, the resistance changing layer 40 maintains a state where the lower end of the filament 30f is slightly separated from the metal layer 50. That is, the resistance changing layer 40 maintains a data retaining state.

However, in the high voltage setting, since the strong filament 30f is formed in the resistance changing layer 40 compared with the intermediate voltage setting, the distance between the filament 30f and the metal layer 50 becomes d3 (<d2) shorter than d2 in the data retaining state. Data written in the nonvolatile memory device 1 in the high voltage setting is set to (1, 0), for example.

Then, when reading the written data, a voltage (Vrd3) of such a degree that the lower end of the filament 30f comes in contact with the metal layer 50 again is applied between the interconnections. This voltage is referred to as a reading voltage (Vrd3).

If the reading voltage (Vrd3) is applied between the interconnections, the lower end of the filament 30f comes in contact with the metal layer 50 again. That is, by applying the reading voltage (Vrd3), it is detected that the resistance changing layer 40 is in the low resistance state.

There is a relationship of “reading voltage (Vrd3)<voltage (Vsth)” between the reading voltage (Vrd3) and the voltage (Vsth). This is because the filament 30f is already formed in the resistance changing layer 40 when the reading voltage (Vrd3) is applied. That is, this is because the distance between the filament 30f and the metal layer 50 is substantially d0 before the high voltage setting, but the distance between the filament 30f and the metal layer 50 becomes d3 shorter than d0 in the data retaining state.

Further, there is a relationship of “reading voltage (Vrd3)<reading voltage (Vrd2)” between the reading voltage (Vrd3) and the reading voltage (Vrd2). This is because there is a relationship of d3<d2 in the distance between the filament 30f and the metal layer 50 in the data retaining state.

As described above, according to the exemplary embodiment, the filaments 30f having the different strengths according to the respective setting operations can be formed in the resistance changing layer 40.

Here, when collectively considering the relationships of the reading voltages after the low voltage setting, after the intermediate voltage setting, and after the high voltage setting, it can be understood that there is a relationship of Vrd3<Vrd2<Vrd1. Accordingly, by using the difference between the reading voltages, it is possible to detect which one of (0, 0), (0, 1), and (1, 0) the data written in the nonvolatile memory device 1 is. That is, it is possible to perform multi-value recording to the storage cell 70 and reading of the data.

In the setting operation, the current flowing between interconnections is appropriately suppressed due to the existence of the current limiting layer 60. Thus, the thickness of the filament 30f is suppressed from becoming excessively thick.

Further, when the data written in the low voltage setting, the intermediate voltage setting, and the high voltage setting is deleted, a reverse voltage (−Vrs) in which the potential of the interconnection layer 20 is lower than the potential of the interconnection layer 10 is applied between the interconnections. Thus, the metal ions 30a diffused in the resistance changing layer 40 move toward the metal ion-source layer 30, so that the filament 30f and the metal layer 50 are in a non-contact state. That is, the resistance changing layer 40 transitions to the high resistance state.

The low voltage setting, the intermediate voltage setting, and the high voltage setting may be executed by applying the same setting voltage for different voltage application times.

The voltage (Vstl) may be read as a first voltage, the voltage (Vstm) may be read as a second voltage, the voltage (Vsth) may be read as a third voltage, the reading voltage (Vrd1) may be read as a sixth voltage, the reading voltage (Vrd2) may be read as a fifth voltage, and the reading voltage (Vrd3) may be read as a fourth voltage. The fourth voltage is lower than the fifth voltage, and the fifth voltage is lower than the sixth voltage.

Further, although not shown in FIG. 2, if data in a reset state is set to (1, 1), data (0, 0) is written as first data, data (0, 1) is written as second data, data (1, 0) is written as third data, and data (1, 1) is written as fourth data, in the resistance changing layer 40. For example, when the lower end of the filament 30f is not in contact with the metal layer 50 even though the reading voltage Vrd1 is applied between the interconnections, it can be detected that the resistance changing layer 40 is in the high resistance state, that is, the data (1, 1).

Further, in the exemplary embodiment, the resistances after the low voltage setting, the intermediate voltage setting, and the high voltage setting are substantially the same, and the resistances after the respective settings are in the low resistance state (R1). Further, the resistance values R0 and R1 are not fixed values, in which the resistance in a state where the lower end of the filament 30f is not in contact with the metal layer 50 is denoted as the resistance value R0, and the resistance value after contact is denoted as the resistance value R1.

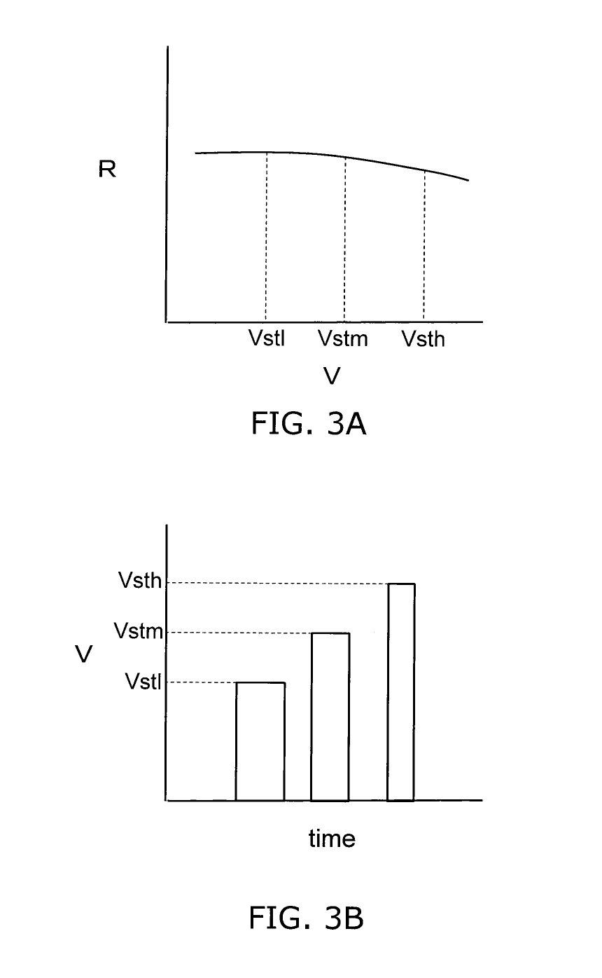

FIG. 3A is an example of a diagram illustrating a resistance-voltage curve of a current limiting layer according to an exemplary embodiment, and FIG. 3B is an example of a diagram illustrating a voltage pulse during the setting operation according to the exemplary embodiment.

There is the following relationship between a resistance value of the resistance changing layer 40 and a resistance value of the current limiting layer 60.

With respect to the relationship between the resistance value of the resistance changing layer 40 and the resistance value of the current limiting layer 60 before the setting operation, if a relationship (1) of “the resistance value of the resistance changing layer 40<<the resistance value of the current limiting layer 60” is established, the voltage is not applied to the resistance changing layer 40 in the setting operation and the metal ions 30a in the resistance changing layer 40 are not easily diffused. That is, the setting operation cannot be performed. On the other hand, if a relationship (2) of “the resistance value of the resistance changing layer 40=the resistance value of the current limiting layer 60” is established, half the voltage applied between electrodes is applied to the resistance changing layer 40. Thus, the setting voltage becomes higher than an optimal value.

Accordingly, before the setting operation, the resistance value of the current limiting layer 60 is set so that a relationship (3) of “the resistance value of the resistance changing layer 40>>the resistance value of the current limiting layer 60” is established.

Subsequently, the relationship between the resistance value of the resistance changing layer 40 and the resistance value of the current limiting layer 60 after the setting operation will be described. After the setting operation, the filament 30f comes in contact with the metal layer 50.

If a relationship (4) of “the resistance value of the resistance changing layer 40>the resistance value of the current limiting layer 60” is established, a current excessively flows in the filament 30f, and thus, the filament 30f may break down.

Accordingly, if a relationship (5) of “the resistance value of the resistance changing layer 40 (resistance value of the filament 30f)<<the resistance value of the current limiting layer 60” is established, the current flowing in the filament 30f can be suppressed by the current limiting layer 60.

In this way, it is preferable that the resistance value of the current limiting layer 60 satisfy the relationship of “the resistance value of the resistance changing layer 40>>the resistance value of the current limiting layer 60” before the setting operation, and satisfy the relationship of “the resistance value of the resistance changing layer 40<<the resistance value of the current limiting layer 60” after the setting operation.

Further, the resistance R of the current limiting layer 60 is not constant with respect to the voltage V, as shown in FIG. 3A, and decreases as the voltage V increases. For example, the resistance R of the current limiting layer 60 is low when the voltage (Vstm) is applied between the interconnections, compared with a case where the voltage (Vstl) is applied between the interconnections, and is low when the voltage (Vsth) is applied between the interconnections compared with a case where the voltage (Vstm) is applied between the interconnections.

As described above, the strength of the filament 30f becomes higher as a higher current flows between the interconnections. In the exemplary embodiment, the current limiting layer 60 of which the resistance R becomes low when the voltage (Vsth) is applied, compared with a case where the voltage (Vstl) is applied, is used. Thus, when the voltage (Vsth) is applied between the interconnections, a relatively high current flows between the interconnections.

For this reason, as shown in FIG. 2, the difference is generated in the strength of the formed filament 30f by the flowed current. Thus, the difference is generated in the distances d1 to d3 in the data retaining state. As a result, the difference is generated in the reset voltage during reading, which enables the multi-value cell.

Further, when the voltage (Vsth) is applied, since a relatively high current flows between the interconnections, as shown in FIG. 3B, the time when the voltage (Vstm) is applied between the interconnections may be set to be shorter than the time when the voltage (Vstl) is applied between the interconnections, and the time when the voltage (Vsth) is applied between the interconnections may be set to be shorter than the time when the voltage (Vstm) is applied between the interconnections.

That is, the control circuit 80 performs a control so that the application time of the voltage (Vstm) is shorter than the application time of the voltage (Vstl) in the intermediate voltage setting. Further, the control circuit 80 performs a control so that the application time of the voltage (Vsth) is shorter than the application time of the voltage (Vstm) in the high voltage setting.

If a current limiting layer in which the resistance is constant with respect to the voltage, or a current limiting layer in which the resistance increases as the voltage increases is used, the voltage (Vsth) in the second setting operation is set to be higher, or the voltage application time is set to be longer. Thus, a higher amount of power is necessary for data writing. Further, the storage cell 70 may break down due to a strong voltage applied to the storage cell 70 and application of a strong electric field for a long time. Here, the breakdown includes a short circuit between the interconnections, an insulation breakdown of the resistance changing layer 40, or the like.

The multi-value recording according to the exemplary embodiment will be described in detail.

Before describing a specific example of the multi-value recording according to the exemplary embodiment, a specific example of binary recording will be described.

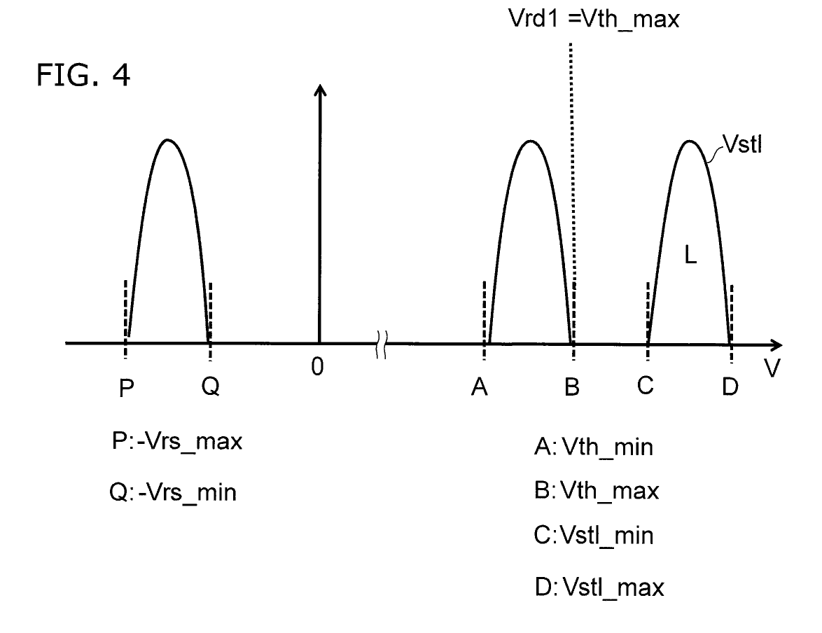

FIG. 4 is a diagram schematically illustrating binary recording according to an exemplary embodiment.

Here, a transverse axis represents a voltage. A longitudinal axis represents the frequency of an applied voltage value in consideration of a design change of a storage cell, variation of the applied voltage value, or the like. As an example of the binary recording, the above-mentioned low voltage setting operation is used.

In the binary recording, the voltage (Vstl) is applied between the interconnections. Thus, the resistance of the resistance changing layer 40 is changed into the resistance value R1 (<R0) from the resistance value R0. That is, the data writing to the nonvolatile memory device 1 is performed.

Here, the voltage (Vstl) creates a histogram by the frequency thereof. For example, a point C represents a minimum value of the voltage (Vstl), and a point D represents a maximum value of the voltage (Vstl).

If the setting operation is completed, a state where the voltage is not applied (0 V) is continued between the interconnections. That is, the resistance changing layer 40 maintains a state where the lower end of the filament 30f is slightly separated from the metal layer 50.

Then, in order to read the written data, the lower end of the filament 30f comes in contact with the metal layer 50 again. That is, a voltage (Vth) of such a degree that the lower end of the filament 30f comes in contact with the metal layer 50 again is applied between the interconnections. In FIG. 4, the data written at the voltage (Vstl) is referred to as “data L”.

The voltage (Vth) creates a histogram according to the variation of the voltage (Vstl). Here, a point A represents a minimum value of the voltage (Vth), and a point B represents a maximum value of the voltage (Vth).

In the exemplary embodiment, in order to reliably read the written data, the maximum value of the voltage (Vth) is set as the reading voltage (Vrd1).

If the reading voltage (Vrd1) is applied between the interconnections, the lower end of the filament 30f comes in contact with the metal layer 50 again, and thus, it can be detected that the resistance changing layer 40 is in the low resistance state (for example, the resistance value R1). On the other hand, if the lower end of the filament 30f is not in contact with the metal layer 50 again even though the reading voltage (Vrd1) is applied between the interconnections, it can be detected that the resistance changing layer 40 is in the high resistance state (for example, the resistance value R0).

When data is deleted, the reverse voltage (−Vrs) is applied between the interconnections. The reverse voltage (−Vrs) creates a histogram according to the variation of the voltage (Vstl). Here, a point P represents a maximum value of the reverse voltage (−Vrs), and a point Q represents a minimum value of the reverse voltage (−Vrs).

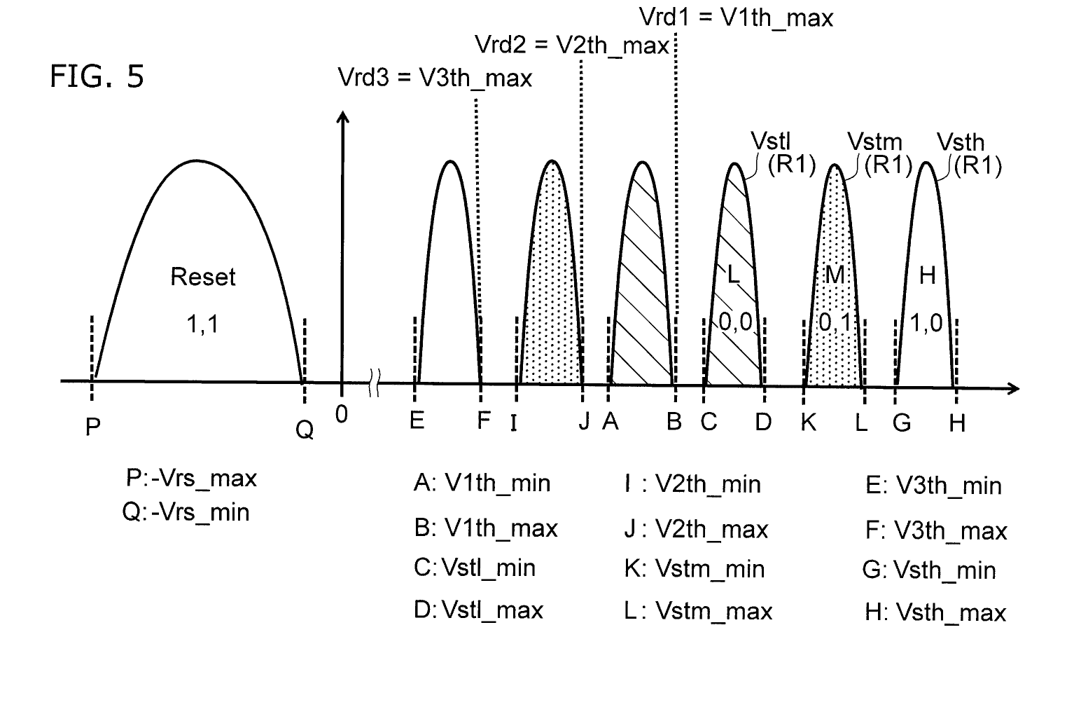

FIG. 5 is a diagram schematically illustrating the multi-value recording according to an exemplary embodiment.

The control circuit 80 performs any one setting operation among the first setting operation, the second setting operation, and the third setting operation when performing the setting operation.

Here, the first setting operation refers to an operation in which the first voltage (Vstl) is applied between the interconnection layer 10 and the interconnection layer 20 to write the data (0, 0) in the resistance changing layer 40. The second setting operation refers to an operation in which the second voltage (Vstm) higher than the first voltage (Vstl) is applied between the interconnection layer 10 and the interconnection layer 20 to write the data (0, 1) in the resistance changing layer 40. The third setting operation refers to an operation in which the third voltage (Vsth) higher than the second voltage (Vstm) is applied between the interconnection layer 10 and the interconnection layer 20 to write the data (1, 0) in the resistance changing layer 40.

For example, in FIG. 5, a transverse axis represents a voltage, and a longitudinal axis represents the frequency of an applied voltage value. In the multi-value recording, the intermediate voltage setting operation and the high voltage setting operation are performed, in addition to the above-mentioned low voltage setting operation. Histograms indicated by hatched lines in FIG. 5 represent the low voltage setting operation and the reading operation described with reference to FIG. 4. Further, in FIG. 5, “Vth” in FIG. 4 is replaced with “V1th”. Histograms indicated by dots in FIG. 5 represent the intermediate voltage setting operation and the reading operation.

In the multi-value recording, the voltage (Vstm) and the voltage (Vsth) in addition to the voltage (Vstl) are applied between the interconnections. By applying the voltage (Vstm), the resistance of the resistance changing layer 40 is changed into the resistance value R1. Further, by applying the voltage (Vsth), the resistance of the resistance changing iayer 40 is changed into the resistance value R1.

The voltage (Vstm) and the voltage (Vsth) create histograms according to their frequencies. Here, a point K represents a minimum value of the voltage (Vstm), and a point L represents a maximum value of the voltage (Vstm). Further, a point G represents a minimum value of the voltage (Vsth), and a point H represents a maximum value of the voltage (Vsth).

If the intermediate voltage setting operation is completed, a state where the voltage is not applied (0 V) is continued between the interconnections. That is, the resistance changing layer 40 maintains a state where the lower end of the filament 30f is slightly separated from the metal layer 50. Further, if the high voltage setting operation is completed, a state where the voltage is not applied (0 V) is continued between interconnections. That is, the resistance changing layer 40 maintains a state where the lower end of the filament 30f is slightly separated from the metal layer 50.

Next, in order to read the written data, the lower end of the filament 30f comes in contact with the metal layer 50 again. That is, a voltage (V2tm) of such a degree that the lower end of the filament 30f comes in contact with the metal layer 50 again is applied between the interconnections. In FIG. 5, the data written at the voltage (Vstm) is referred to as “data M”. Further, similarly, when a voltage (V2th) is applied between the interconnections, the lower end of the filament 30f comes in contact with the metal layer 50 again. In FIG. 5, the data written at the voltage (Vsth) is referred to as “data H”.

The voltage (V2tm) creates a histogram according to the variation of the voltage (Vstm). Similarly, the voltage (V2th) creates a histogram according to the variation of the voltage (Vsth). The histogram of the voltage (V2tm) is located on the left side of the histogram of the voltage (V1tm). The histogram of the voltage (V2th) is located on the left side of the histogram of the voltage (V1th). This is because the distance between the filament 30f and the metal layer 50 satisfies d3<d2<d1 in the data retaining state. Here, a point I represents a minimum value of the voltage (V2tm), and a point J represents a maximum value of the voltage (V2tm). Further, a point E represents a minimum value of the voltage (V2th), and a point F represents a maximum value of the voltage (V2th).

In the exemplary embodiment, in order to reliably read the written data in the high voltage setting operation, the maximum value of the voltage (V2tm) is set as the reading voltage (Vrd2), and the maximum value of the voltage (V2th) is set as the reading voltage (Vrd3).

If the reading voltage (Vrd2) is applied between the interconnections, the lower end of the filament 30f comes in contact with the metal layer 50 again, and thus, it can be detected that the resistance changing layer 40 is in the low resistance state (R1). Similarly, if the reading voltage (Vrd3) is applied between the interconnections, the lower end of the filament 30f comes in contact with the metal layer 50 again, and thus, it can be detected that the resistance changing layer 40 is in the low resistance state (R1).

Here, since the reading voltage (Vrd2) is lower than the reading voltage (Vrd1), even though the reading voltage (Vrd2) is applied, the resistance changing layer 40 in which the data is written in the low voltage setting operation does not enter a lower resistance state. Further, since the reading voltage (Vrd3) is lower than the reading voltage (Vrd1) and the reading voltage (Vrd2), even though the reading voltage (Vrd3) is applied, the resistance changing layer 40 in which the data is written in the low voltage setting operation and the resistance changing layer 40 in which the data is written in the intermediate voltage setting operation do not enter a lower resistance state. That is, when reading the data H, it is sufficient if the reading voltage (Vrd3) is applied between the interconnections, and when reading the data M, it is sufficient if the reading voltage (Vrd2) is applied between the interconnections (described later).

Further, when reading the data L, the reading voltage (Vrd3) is first applied between the interconnections, and it is detected that the resistance changing layer 40 is in the resistance state (R1). Here, if it is not detected that the resistance changing layer 40 is in the resistance state (R1), the reading voltage (Vrd2) is applied between the interconnections, and it is detected that the resistance changing layer 40 is in the resistance state (R1). Here, if it is not detected that the resistance changing layer 40 is in the resistance state (R1), the reading voltage (Vrd1) is applied between the interconnections, and it is detected that the resistance changing layer 40 is in the resistance state (R1).

In the multi-value reading, since the low voltage setting operation, the intermediate voltage setting operation, and the high voltage setting operation are performed, the width of the histogram of the reverse voltage (−Vrs) shown in FIG. 5 becomes wider than the width of the histogram of the reverse voltage (−Vrs) shown in FIG. 4.

Voltage values at the points A to H are within 10 V, for example.

The above-described writing operation and reading operation are automatically controlled by the control circuit 80.

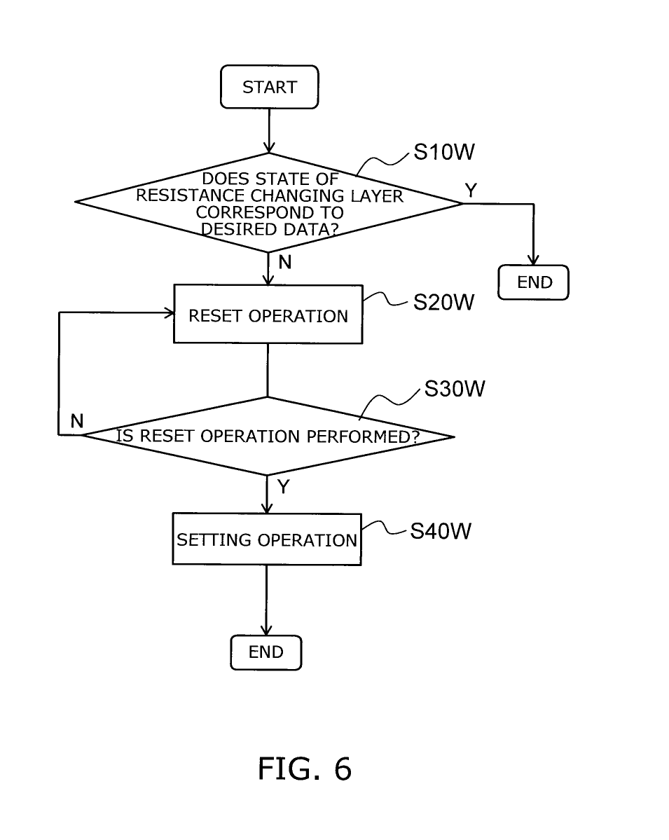

FIG. 6 is a diagram illustrating the flow of writing according to an exemplary embodiment.

The control circuit 80 detects (determines) whether the state of the resistance changing layer 40 corresponds to desired data before performing the setting operation (step S10W).

Here, if the state of the resistance changing layer 40 corresponds to the desired data, the control circuit 80 maintains the state as it is (end). For example, when the data (0, 0) is to be written in the resistance changing layer 40 as the data, if the state of the resistance changing layer 40 is already the data (0, 0), it is not necessary to write the data.

The detection of step S10W may be executed by the same flow as in steps S10R to S70R to be described later.

Then, if it is determined that the state of the resistance changing layer 40 does not correspond to the desired data, the control circuit 80 performs the reset operation for the resistance changing layer 40 (step S20W).

For example, if the first setting operation is performed for the resistance changing layer 40, the control circuit 80 detects whether the data (0, 0) is written in the resistance changing layer 40 before performing the first setting operation. Subsequently, if it is determined that the data (0, 0) is not written in the resistance changing layer 40, the control circuit 80 performs a control so that a reset voltage is applied between the interconnection layer 10 and the interconnection layer 20. Here, the reset voltage is a voltage in which a high potential is supplied to the interconnection layer 10 compared with the interconnection layer 20. Thus, the resistance of the resistance changing layer 40 is set to be higher than the resistance value R1 (reset state).

Alternatively, when the second setting operation is performed for the resistance changing layer 40, the control circuit 80 detects whether the data (0, 1) is written in the resistance changing layer 40 before performing the second setting operation. Subsequently, if it is determined that the data (0, 1) is not written in the resistance changing layer 40, the control circuit 80 performs the reset operation for the resistance changing layer 40.

Alternatively, when the third setting operation is performed for the resistance changing layer 40, the control circuit 80 detects whether the data (1, 0) is written in the resistance changing layer 40 before performing the third setting operation. Subsequently, if it is determined that the data (1, 0) is not written in the resistance changing layer 40, the control circuit 80 performs the reset operation for the resistance changing layer 40.

Then, the control circuit 80 determines whether the reset operation is performed for the resistance changing layer 40 (step S30W).

Here, if it is determined that the resistance changing layer 40 is not in the reset state, the control circuit 80 performs the reset operation for the resistance changing layer 40 again.

Further, if it is determined that the resistance changing layer 40 is in the reset state, the control circuit 80 performs the reset operation for the resistance changing layer 40 (step S40W).

In the setting operation, the control circuit 80 performs a control so that the voltage (Vstl) is applied between the interconnection layer 10 and the interconnection layer 20 (first setting operation).

Alternatively, the control circuit 80 performs a control so that the voltage (Vstm) higher than the voltage (Vstl) is applied between the interconnection layer 10 and the interconnection layer 20 (second setting operation).

Alternatively, the control circuit 80 performs a control so that the voltage (Vsth) higher than the voltage (Vstm) is applied between the interconnection layer 10 and the interconnection layer 20 (third setting operation).

After the resistance of the resistance changing layer 40 becomes the resistance value R1 by any one of the above-mentioned setting operations, the control circuit 80 performs a control so that the voltage application between the interconnection layer 10 and the interconnection layer 20 is stopped. That is, after any one setting operation among the first setting operation, the second setting operation, and the third setting operation is performed, the voltage supply between the interconnections is stopped, and thus, each piece of data recorded in the resistance changing layer 40 is retained.

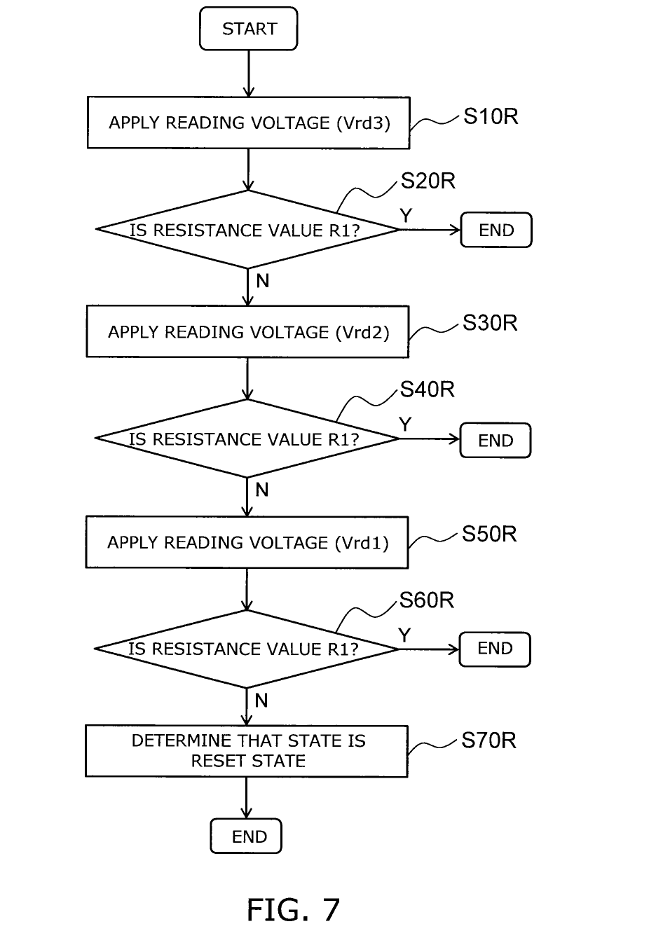

FIG. 7 is a diagram illustrating the flow of reading according to an exemplary embodiment.

After the setting operation, the control circuit 80 performs the following reading operation. The reading operation is referred to as a re-setting operation.

In the reading operation, the reading voltage is sequentially applied from the lowest reading voltage to the highest reading voltage to the resistance changing layer 40. This order is necessary for preventing the shape of the thin filament 30f written at the lowest writing voltage from being deformed when the reading voltage is applied from the highest reading voltage to the resistance changing layer 40 during the data reading.

For example, the control circuit 80 performs a control so that the reading voltage (Vrd3) lower than the voltage (Vstl) is applied between the interconnection layer 10 and the interconnection layer 20 (step S10R).

Then, the control circuit 80 detects whether the data written in the resistance changing layer 40 is the data (1, 0). The detection of the data (1, 0) is performed based on a change of the resistance between the interconnection layer 10 and the interconnection layer 20 before and after the reading voltage (Vrd3) is applied between the interconnection layer 10 and the interconnection layer 20. For example, the control circuit 80 detects whether the resistance of the resistance changing layer 40 transitions to the resistance value R1 that is the low resistance (step S20R).

Here, if the resistance of the resistance changing layer 40 is the resistance value R1, the control circuit 80 determines that the state of the resistance changing layer 40 is the data (1, 0). That is, the control circuit 80 can read the data (1, 0) (end).

Further, if it is determined that the data written in the resistance changing layer 40 is not the data (1, 0), in other words, if it is determined that the resistance of the resistance changing layer 40 does not transition to the resistance value R1, the control circuit 80 performs a control so that the reading voltage (Vrd2) is applied between the interconnection layer 10 and the interconnection layer 20 (step S30R). Here, the reading voltage (Vrd2) is higher than the reading voltage (Vrd3), and is lower than the voltage (Vstl).

Subsequently, the control circuit 80 detects whether the data written in the resistance changing layer 40 is the data (0, 1). The detection of the data (0, 1) is performed based on the change of the resistance between the interconnection layer 10 and the interconnection layer 20 before and after the reading voltage (Vrd2) is applied between the interconnection layer 10 and the interconnection layer 20. For example, the control circuit 80 detects whether the resistance of the resistance changing layer 40 transitions to the resistance value R1 that is the low resistance (step S40R).

Here, if the resistance of the resistance changing layer 40 is the resistance value R1, the control circuit 80 determines that the state of the resistance changing layer 40 is the data (0, 1). That is, the control circuit 80 can read the data (0, 1) (end).

Further, if it is determined that the data written in the resistance changing layer 40 is not the data (0, 1), in other words, if it is determined that the resistance of the resistance changing layer 40 does not transition to the resistance value R1, the control circuit 80 performs a control so that the reading voltage (Vrd1) is applied between the interconnection layer 10 and the interconnection layer 20 (step S50R). Here, the reading voltage (Vrd1) is higher than the reading voltage (Vrd2), and is lower than the voltage (Vstl).

Subsequently, the control circuit 80 detects whether the data written in the resistance changing layer 40 is the data (0, 0). The detection of the data (0, 0) is performed based on the change of the resistance between the interconnection layer 10 and the interconnection layer 20 before and after the reading voltage (Vrd1) is applied between the interconnection layer 10 and the interconnection layer 20. For example, the control circuit 80 detects whether the resistance of the resistance changing layer 40 transitions to the resistance value R1 that is the low resistance (step S60R).

Here, if the resistance of the resistance changing layer 40 is the resistance value R1, the control circuit 80 determines that the state of the resistance changing layer 40 is the data (0, 0). That is, the control circuit 80 can read the data (0, 0) (end).

Further, if it is determined that the resistance of the resistance changing layer 40 is not the resistance value R1, the control circuit 80 determines that the state of the resistance changing layer 40 is the reset state (data (1, 1)) (step S70R).

The embodiments have been described above with reference to examples. However, the embodiments are not limited to these examples. More specifically, these examples can be appropriately modified in design by those skilled in the art. Such modifications are also encompassed within the scope of the embodiments as long as they include the features of the embodiments. The components included in the above examples and the layout, material, condition, shape, size and the like thereof are not limited to those illustrated, but can be appropriately modified.

Furthermore, the components included in the above embodiments can be combined as long as technically feasible. Such combinations are also encompassed within the scope of the embodiments as long as they include the features of the embodiments. In addition, those skilled in the art could conceive various modifications and variations within the spirit of the embodiments. It is understood that such modifications and variations are also encompassed within the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A nonvolatile memory device comprising:
a first interconnection layer;
a second interconnection layer;
an ion source provided between the first interconnection layer and the second interconnection layer;
a resistance layer provided between the ion source and the first interconnection layer; and
a control circuit writing multi-value data in the resistance layer by changing a setting voltage to be applied between the first interconnection layer and the second interconnection layer when performing a setting operation of writing data in the resistance layer, and the control circuit reading the multi-value data based on reading voltage to be applied between the first interconnection layer and the second interconnection layer when performing a reading operation of reading the multi-value data.

2. The device according to claim 1, wherein,
the control circuit changes an application time of the setting voltage when performing the setting operation of writing data in the resistance layer.

3. The device according to claim 1, wherein,
when performing the setting operation, the control circuit performs any one setting operation among a first setting operation of applying a first voltage between the first interconnection layer and the second interconnection layer to write first data in the resistance layer, a second setting operation of applying a second voltage higher than the first voltage between the first interconnection layer and the second interconnection layer to write second data in the resistance layer, and a third setting operation of applying a third voltage higher than the second voltage between the first interconnection layer and the second interconnection layer to write third data in the resistance layer.

4. The device according to claim 3, wherein,
when performing the reading operation, the control circuit performs a control so that
a fourth voltage lower than the first voltage is applied between the first interconnection layer and the second interconnection layer to detect whether the data written in the resistance layer is the third data,
if determined that the data written in the resistance layer is not the third data, a fifth voltage higher than the fourth voltage and lower than the first voltage is applied between the first interconnection layer and the second interconnection layer to detect whether the data written in the resistance layer is the second data, and
if determined that the data written in the resistance layer is not the second data, a sixth voltage higher than the fifth voltage and lower than the first voltage is applied between the first interconnection layer and the second interconnection layer to detect whether the data written in the resistance layer is the first data.

5. The device according to claim 4, wherein,
the detection of the third data is performed based on a change of a resistance between the first interconnection layer and the second interconnection layer before and after the fourth voltage is applied between the first interconnection layer and the second interconnection layer,
the detection of the second data is performed based on a change of a resistance between the first interconnection layer and the second interconnection layer before and after the fifth voltage is applied between the first interconnection layer and the second interconnection layer, and
the detection of the first data is performed based on a change of a resistance between the first interconnection layer and the second interconnection layer before and after the sixth voltage is applied between the interconnections.

6. The device according to claim 3, wherein,
the control circuit
detects whether the first data is written in the resistance layer before performing the first setting operation, and performs a reset operation of applying a potential higher than a potential of the second interconnection layer to the first interconnection layer if determined that the first data is not written in the resistance layer, or
detects whether the second data is written in the resistance layer before performing the second setting operation, and performs the reset operation if determined that the second data is not written in the resistance layer, or
detects whether the third data is written in the resistance layer before performing the third setting operation, and performs the reset operation if determined that the third data is not written in the resistance layer.

7. The device according to claim 3, wherein,
the control circuit performs a control so that the voltage application between the first interconnection layer and the second interconnection layer is stopped after any one of the first setting operation, the second setting operation, and the third setting operation is performed.

8. The device according to claim 3, further comprising:
a current limiting layer provided between the first interconnection layer and the resistance layer or between the second interconnection layer and the ion source,
wherein a resistance of the current limiting layer is low when the second voltage is applied between the first interconnection layer and the second interconnection layer compared with a case where the first voltage is applied between the first interconnection layer and the second interconnection layer, and is low when the third voltage is applied between the first interconnection layer and the second interconnection layer compared with a case where the second voltage is applied between the first interconnection layer and the second interconnection layer.

9. The device according to claim 8, wherein,
when performing the second setting operation, the control circuit performs a control so that an application time of the second voltage is shorter than an application time of the first voltage.

10. The device according to claim 8, wherein,
when performing the second setting operation, the control circuit performs a control so that an application time of the third voltage is shorter than an application time of the second voltage.

11. The device according to claim 8, wherein,
the resistance of the current limiting layer is lower than the resistance of the resistance layer before the setting operation, and is higher than the resistance of the resistance layer after the setting operation.

12. The device according to claim 8, wherein,
the current limiting layer is provided between the first interconnection layer and the resistance layer, and
a third interconnection layer is further provided between the resistance layer and the current limiting layer.

13. A method for driving a nonvolatile memory device including a first interconnection layer, a second interconnection layer, an ion source that is provided between the first interconnection layer and the second interconnection layer, and a resistance layer provided between the ion source and the first interconnection layer, the method comprising:
writing multi-value data in the resistance layer by changing a setting voltage to be applied between the first interconnection layer and the second interconnection layer when performing a setting operation of writing data in the resistance layer; and
reading the multi-value data based on reading voltage to be applied between the first interconnection layer and the second interconnection layer when performing a reading operation of reading multi-value data.

14. The method according to claim 13, wherein,
an application time of the setting voltage is changed when performing the setting operation of writing data in the resistance layer.

15. The method according to claim 13, further comprising:
performing any setting operation among a first setting operation of applying a first voltage between the first interconnection layer and the second interconnection layer to write first data in the resistance layer, a second setting operation of applying a second voltage higher than the first voltage between the first interconnection layer and the second interconnection layer to write second data in the resistance layer, and a third setting operation of applying a third voltage higher than the second voltage between the first interconnection layer and the second interconnection layer to write third data in the resistance layer when performing the setting operation.

16. The method according to claim 15, further comprising:
when performing the reading operation,
applying a fourth voltage lower than the first voltage between the first interconnection layer and the second interconnection layer to detect whether the data written in the resistance layer is the third data,
applying a fifth voltage higher than the fourth voltage and lower than the first voltage between the first interconnection layer and the second interconnection layer to detect whether the data written in the resistance layer is the second data if determined that the data written in the resistance layer is not the third data, and
applying a sixth voltage higher than the fifth voltage and lower than the first voltage between the first interconnection layer and the second interconnection layer to detect whether the data written in the resistance layer is the first data if determined that the data written in the resistance layer is not the second data.

17. The method according to claim 16, wherein,
the detection of the third data is performed based on a change of a resistance between the first interconnection layer and the second interconnection layer before and after the fourth voltage is applied between the first interconnection layer and the second interconnection layer,
the detection of the second data is performed based on a change of a resistance between the first interconnection layer and the second interconnection layer before and after the fifth voltage is applied between the first interconnection layer and the second interconnection layer, and
the detection of the first data is performed based on a change of a resistance between the first interconnection layer and the second interconnection layer before and after the sixth voltage is applied between the first interconnection layer and the second interconnection layer.

18. The method according to claim 15, further comprising:
detecting whether the first data is written in the resistance layer before performing the first setting operation, and performing a reset operation of applying a potential higher than that of the second interconnection layer to the first interconnection layer if determined that the first data is not written in the resistance layer, or
detecting whether the second data is written in the resistance layer before performing the second setting operation, and performing the reset operation if determined that the second data is not written in the resistance layer, or
detecting whether the third data is written in the resistance layer before performing the third setting operation, and performing the reset operation if determined that the third data is not written in the resistance layer.

19. The method according to claim 15, further comprising:
stopping the voltage application between the first interconnection layer and the second interconnection layer after any one of the first setting operation, the second setting operation, and the third setting operation is performed.
